(19) United States
(12) Patent Application Publication
(10) Pub. No.: US 2024/0145893 A1
(43) Pub. Date: May 2, 2024

(54) RADIO FREQUENCY FILTERS COVERED BY PRINTED CIRCUIT BOARDS

(71) Applicant: CommScope Technologies LLC, Hickory, NC (US)

(72) Inventors: Fusheng Lv, Suzhou (CN); Ligang Wu, Suzhou (CN); Fan He, Suzhou (CN); Giuseppe Resnati, Seregno (IT); Andrea Manzoni, Missaglia (IT); Pietro Maressa, Agrate Brianza (IT); Zhanming Zhang, Suzhou (CN)

(21) Appl. No.: 18/343,163

(22) Filed: Jun. 28, 2023

(30) Foreign Application Priority Data
Oct. 28, 2022 (IT) 102022000022329

(51) Int. Cl. H01P 1/203; H01P 7/06

(52) U.S. Cl. CPC H01P 1/20354; H01P 7/06

(57) ABSTRACT

Radio frequency (RF) devices are provided. An RF device includes one or more resonators. The RF device includes an RF connector that is coupled to the resonator(s). Moreover, the RF device includes a printed circuit board that covers the resonator(s) and is coupled to the resonator(s) via the RF connector.

### CROSS-REFERENCE TO PRIORITY APPLICATION

The present application claims priority to Italian Patent Application No. 102022000022329, filed Oct. 28, 2022, the disclosure of which is hereby incorporated herein by reference in its entirety.

### FIELD

The present disclosure relates to communications systems and, in particular, to radio frequency (“RF”) filters.

### BACKGROUND

Base station antennas for wireless communications systems are used to provide cellular communications service to fixed and mobile users that are within defined coverage areas of the respective base station antennas. These base station antennas typically include one or more linear arrays or two-dimensional arrays of radiating elements, such as dipole, or crossed-dipole, radiating elements that act as individual antenna elements. Each of these arrays may be connected to one or more RF ports. The RF ports are used to pass RF signals between the arrays and one or more radios.

Example base station antennas are discussed in International Publication No. WO 2017/165512 to Bisiules, U.S. patent application Ser. No. 15/921,694 to Bisiules et al., and U.S. Patent Application No. 63/024,846 to Hamdy et al., the disclosures of which are hereby incorporated herein by reference in their entireties. Many cellular base stations include RF filters that are mounted within a base station antenna or on an antenna tower adjacent the base station antenna. As an example, a cellular base station may include (i) a base station antenna having one or more arrays of radiating elements, (ii) a radio that is coupled to the array(s), and (iii) one or more RF filters that are coupled between the radio and the array(s). For example, the RF filter(s) may be part of an RF feed network for the array(s).

### SUMMARY

An RF device, according to some embodiments, may include an RF filter including a resonator. The RF device may include an RF connector that is coupled to the resonator. Moreover, the RF device may include a printed circuit board (“PCB”) that covers the resonator and is coupled to the resonator via the RF connector.

In some embodiments, the RF connector may include a pogo pin connector.

According to some embodiments, the PCB may include a plated through hole (“PTH”), and the RF connector may include a conductive pin that is coupled to the PTH. A first surface of the PCB may be opposite a second surface of the PCB and may be closer than the second surface to the resonator. Moreover, the conductive pin may extend into the PTH and may be soldered to the second surface.

In some embodiments, the RF device may include a metal cover that is between the PCB and the resonator. The RF connector may extend through an opening in the metal cover.

According to some embodiments, the RF device may include a conductive ring that is between the metal cover and the PCB. The RF connector may extend through the conductive ring.

In some embodiments, the RF filter may include a conductive housing having walls that extend around the resonator. Moreover, the PCB may not be soldered to the conductive housing.

According to some embodiments, the metal cover may include a grounding pin that is adjacent the opening and extends into the PCB. The grounding pin may be a first of at least three grounding pins of the metal cover that are adjacent the opening and extend into the PCB. For example, the at least three grounding pins may be respective punched portions of the metal cover.

In some embodiments, the PCB may include a plurality of PTHs. A first surface of the PCB may be opposite a second surface of the PCB and may be closer than the second surface to a flat primary surface of the metal cover. The at least three grounding pins may extend through respective ones of the PTHs and may be soldered to the second surface. Moreover, the at least three grounding pins may include four grounding pins.

According to some embodiments, the RF filter may include a conductive housing having walls that extend around the resonator. The RF connector may be a first RF connector that is at least partially inside the conductive housing. The RF device may include a second RF connector that is at least partially inside the conductive housing. Moreover, the resonator may be coupled between the first and second RF connectors.

In some embodiments, the resonator may be a first of a plurality of resonators that are coupled between the first and second RF connectors. The PCB may be a feed board that is configured to feed a plurality of radiating elements. The first RF connector may be coupled between the resonators and the feed board. The second RF connector may be coupled between the resonators and a radio that is coupled to the radiating elements via the RF device.

According to some embodiments, the resonator may be a first of a plurality of resonators that are coupled between the first and second RF connectors. The PCB may be coupled between the first RF connector and a radio. Moreover, the second RF connector may be coupled between the resonators and a plurality of radiating elements that are coupled to the radio via the RF device.

An RF device, according to some embodiments, may include an RF filter having a plurality of resonators. The RF device may include a metal cover that covers the resonators. The RF device may include a PCB that covers the metal cover. The RF device may include a conductive material that is between the metal cover and the PCB. Moreover, the RF device may include a conductive pin that extends through the metal cover and the conductive material and couples the resonators and the PCB to each other.

In some embodiments, the conductive pin may include a pogo pin connector. The conductive material may include metal that is inside a ring that extends around the pogo pin connector. Moreover, the metal cover may have a flat primary surface and an annular portion that protrudes from the flat primary surface away from the PCB and extends around the pogo pin connector.

According to some embodiments, the RF filter may include a conductive housing having walls that extend around the resonators. Moreover, the PCB may not be soldered to the conductive housing.

In some embodiments, the metal cover may include an adjustable tuning element therein, and the PCB may have an opening that corresponds to the adjustable tuning element.

An RF device, according to some embodiments, may include an RF filter having a plurality of resonators. The RF device may include a PCB feed board that covers the resonators. Moreover, the RF device may include a pogo pin connector that couples the resonators and the PCB feed board to each other.

In some embodiments, the RF filter may include a conductive housing having walls that extend around the resonators. The PCB feed board may be soldered to the conductive housing.

According to some embodiments, the RF device may include a metal cover that is between the resonators and the PCB feed board. The pogo pin connector may extend through an opening in the metal cover.

In some embodiments, the metal cover may include an adjustable tuning element. The PCB feed board may include an opening that corresponds to the adjustable tuning element.

According to some embodiments, the metal cover may include a plurality of grounding pins that are adjacent the opening and extend into the PCB feed board. For example, the grounding pins may be respective punched portions of the metal cover. Moreover, the PCB feed board may include a plurality of PTHs, a first surface of the PCB feed board may be opposite a second surface of the PCB feed board and closer than the second surface to a flat primary surface of the metal cover, and the grounding pins may extend through respective ones of the PTHs and may be soldered to the second surface.

### BRIEF DESCRIPTION OF THE DRAWINGS

FIG. 1A is a front perspective view of a base station antenna, according to embodiments of the present invention.

FIG. 1B is a front perspective view of the base station antenna of FIG. 1A electrically connected to a radio.

FIG. 1C is a schematic block diagram of ports of the base station antenna of FIG. 1A electrically connected to ports of the radio of FIG. 1B.

FIGS. 2A, 3A, 4A, 5A, and 6A are exploded side perspective views of different examples of an RF cavity filter of the filter device of FIG. 1C, according to embodiments of the present invention.

FIGS. 2B, 3B, 4B, 5B, and 6B are exploded side views of the filters of FIGS. 2A, 3A, 4A, 5A, and 6A, respectively.

FIG. 7 is a front perspective view of a metal cover that includes a plurality of tuning elements, according to embodiments of the present invention.

FIG. 8 is a schematic cross-sectional view of a PCB with openings therein that correspond to the tuning elements, respectively, of FIG. 7.

FIG. 9 is a schematic side view of a feed board that covers the resonators of FIG. 6A.

FIG. 10 is a schematic side view of an adaptor board that covers the resonators of FIG. 2A.

FIG. 11 is a front perspective view of a base station antenna radome, according to other embodiments of the present invention.

### DETAILED DESCRIPTION

Pursuant to embodiments of the present invention, RF devices are provided that increase integration between an RF filter and a cellular base station antenna, and/or between the filter and a radio that is coupled to radiating elements of the antenna via the filter. Such integration may be desirable in the case of, for example, a massive multi-input-multi-output (“N IMO”) antenna, for which it may be advantageous to reduce size (e.g., dimensions, profile, and/or weight) and cost.

In some embodiments, a conductive housing of an RE cavity filter may be covered by a PCB. For example, resonators that are inside the housing may be covered by a PCB feed board or a PCB adaptor board, and the resonators may be coupled to the PCB by an RF connector (e.g., a pin-type connector, such as a pogo pin connector) that is at least partially inside the housing. As used herein, the phrase “inside the housing” may refer to being located in a cavity defined (e.g., surrounded) by walls of the housing. The integrated filter, PCB, and RF connector may help to reduce the dimensions, weight, and/or cost of a cellular base station antenna.

Moreover, electromagnetic shielding for the RF connector may be provided by, for example, a conductive ring or built-in grounding pins of a metal cover that is between the PCB and the resonators. In some embodiments, the PCB may not be soldered to the housing, as the metal cover may be between the PCB and the housing. In other embodiments, the metal cover may be omitted, the PCB may be soldered to the housing, and no grounding pin or RF connector may be soldered to the PCB.

Example embodiments of the present invention will be described in greater detail with reference to the attached figures.

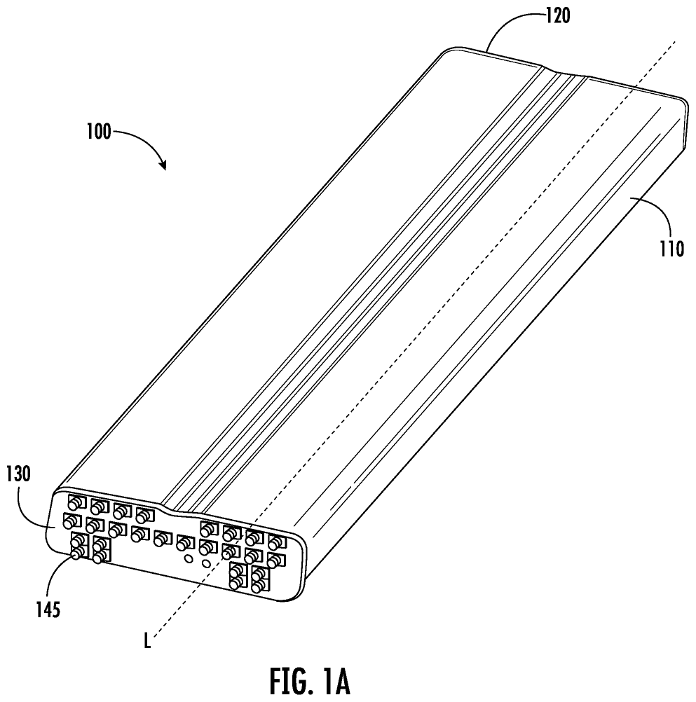

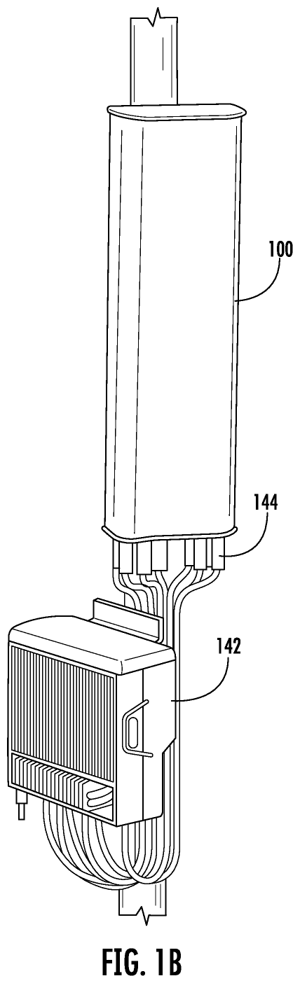

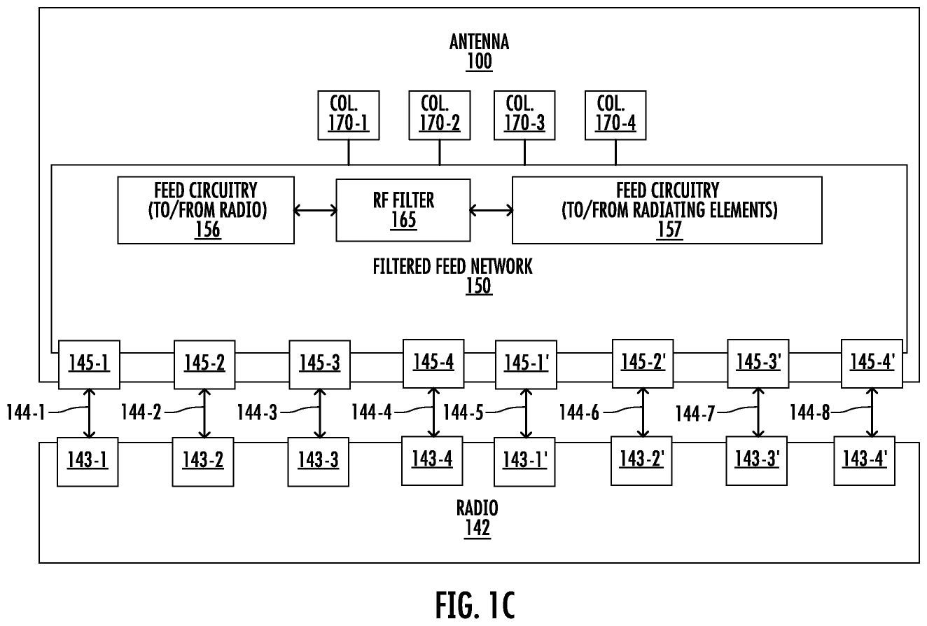

FIG. 1A is a front perspective view of a base station antenna 100, according to embodiments of the present invention. The antenna 100 may be, for example, a cellular base station antenna at a macrocell base station. As shown in FIG. 1A, the antenna 100 is an elongated structure and has a generally rectangular shape. The antenna 100 includes a radome 110. In some embodiments, the antenna 100 further includes a top end cap 120 and/or a bottom end cap 130. The bottom end cap 130 may include a plurality of RF connectors 145 mounted therein. The connectors 145, which may also be referred to herein as “ports,” are not limited, however, to being located on the bottom end cap 130. Rather, one or more of the connectors 145 may be provided on, for example, the rear (i.e., back) side of the radome 110 that is opposite the front side of the radome 110. The antenna 100 is typically mounted in a vertical configuration (i.e., the long side of the antenna 100 extends along a vertical axis L with respect to Earth).

FIG. 1B is a front perspective view of the base station antenna 100 electrically connected to a radio 142 by RF transmission lines 144, such as coaxial cables. For example, the radio 142 may be a cellular base station radio, and the antenna 100 and the radio 142 may be located at (e.g., may be components of) a cellular base station. In some cases, the radio 142 may be mounted on the back surface of the antenna 100 rather than below the antenna 100.

FIG. 1C is a schematic block diagram of ports 145 of the base station antenna 100 electrically connected to respective ports 143 of the radio 142. As shown in FIG. 1C, ports 145-1 through 145-4 of the antenna 100 are electrically connected to ports 143-1 through 143-4, respectively, of the radio 142 by respective RF transmission lines 144-1 through 144-4, such as coaxial cables. Similarly, ports 145-1′ through 145-4′ of the antenna 100 are electrically connected to ports 143-1′ through 143-4′, respectively, of the radio 142 by respective RF transmission lines 144-5 through 144-8. The ports 145-1 through 145-4 may transmit and/or receive RF signals in the same frequency band as the ports 145-1′ through 145-4′, or in a different frequency band from the ports 145-1′ through 145-4′. For simplicity of illustration, only eight ports 145 are shown in FIG. 1C. In some embodiments, however, the antenna 100 may include twelve, twenty, thirty, or more ports 145. Moreover, though all of the ports 143 are shown as being part of a single radio 142, it will be appreciated that the ports 143 may alternatively be spread across multiple radios 142.

The antenna 100 may transmit and/or receive RF signals in one or more frequency bands, such as one or more bands comprising frequencies between 3.4 gigahertz (“GHz”) and 3.8 GHz. For example, the antenna 100 may, in some embodiments, transmit and/or receive RF signals in all or a portion of the band(s), while rejecting RF signals outside of the band(s).

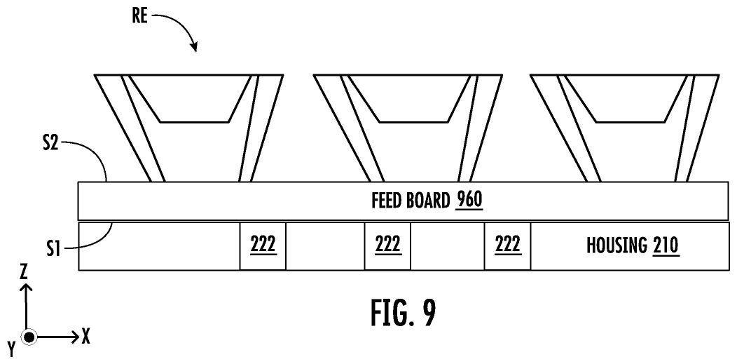

The antenna 100 may include arrays (e.g., vertical columns) 170-1 through 170-4 of radiating elements RE (FIG. 9) that are configured to transmit and/or receive RF signals. The antenna 100 may also include a filtered feed network 150 that is coupled between the arrays 170 and the radio 142. For example, the arrays 170 may be coupled to respective RF transmission paths (e.g., including one or more RF transmission lines) of the feed network 150.

The arrays 170 may be spaced apart from each other in a horizontal direction Y (FIG. 9) and may each extend in a vertical direction X (FIG. 9) from a lower portion of an antenna assembly to an upper portion of the antenna assembly. The direction X may be, or may be parallel with, the longitudinal axis L (FIG. 1A). The direction X may also be perpendicular to the direction Y and a forward direction Z. As used herein, the term “vertical” does not necessarily require that something is exactly vertical (e.g., the antenna 100 may have a small mechanical down-tilt).

The arrays 170 are each configured to transmit and/or receive RF signals in one or more frequency bands, such as one or more bands comprising frequencies between 3.4 GHz and 3.8 GHz. For example, the feed network 150 may include one or more RF filter devices 165, which may comprise a band-pass filter that is configured to pass frequencies between 3.4 GHz and 3.8 GHz. Though FIG. 1C illustrates four arrays 170-1 through 170-4, the antenna assembly may include more (e.g., five, six, or more) or fewer (e.g., three, two, or one) arrays 170. Moreover, the number of radiating elements RE in an array 170 can be any quantity from two to twenty or more. For example, the four arrays 170-1 through 170-4 shown in FIG. 1C may each have three to twenty radiating elements RE. According to some embodiments, the arrays 170 may each have the same number (e.g., eight) of radiating elements RE.

Feed circuitry 156 of the feed network 150 may be coupled between each filter device 165 and the radio 142. The feed network 150 may also include feed circuitry 157 that is coupled between the filter device(s) 165 and the arrays 170. The circuitry 156/157 can couple downlink RF signals from the radio 142 to radiating elements RE that are in arrays 170. The circuitry 156/157 may also couple uplink RF signals from radiating elements RE that are in arrays 170 to the radio 142. For example, the circuitry 156/157 may include power dividers, RF switches, RF couplers, and/or RF transmission lines that couple the filter device(s) 165 between the radio 142 and the arrays 170.

In some embodiments, the circuitry 156/157 may be integrated with an RF filter device 165. As an example, the circuitry 156 may be on a first PCB that covers a conductive housing of the filter device 165, and the circuitry 157 may be on a second PCB that covers the conductive housing.

Moreover, the antenna 100 may include phase shifters that are used to electronically adjust the tilt angle of the antenna beams generated by each array 170. The phase shifters may be located at any appropriate location along the RF transmission paths that extend between the ports 145 and the arrays 170. Accordingly, though omitted from view in FIG. 1C for simplicity of illustration, the feed network 150 may include phase shifters.

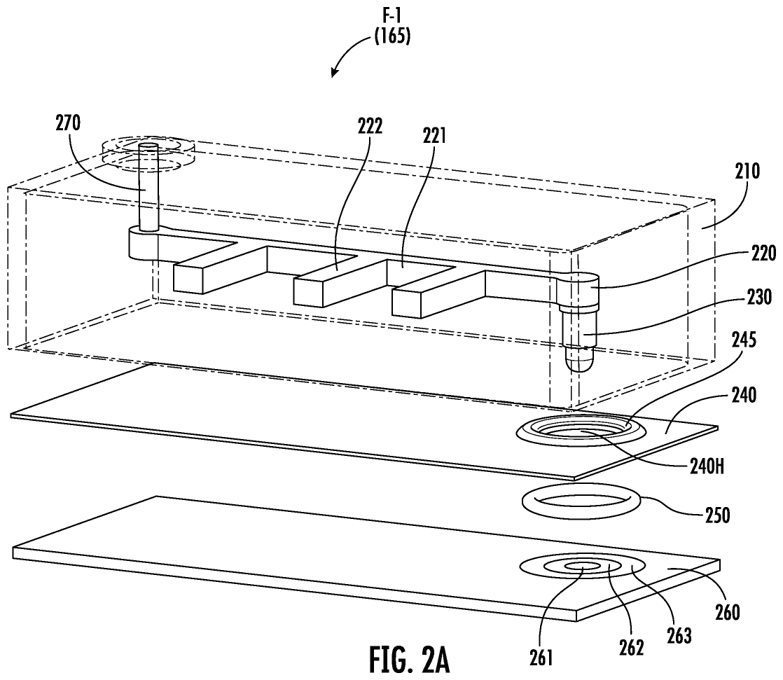

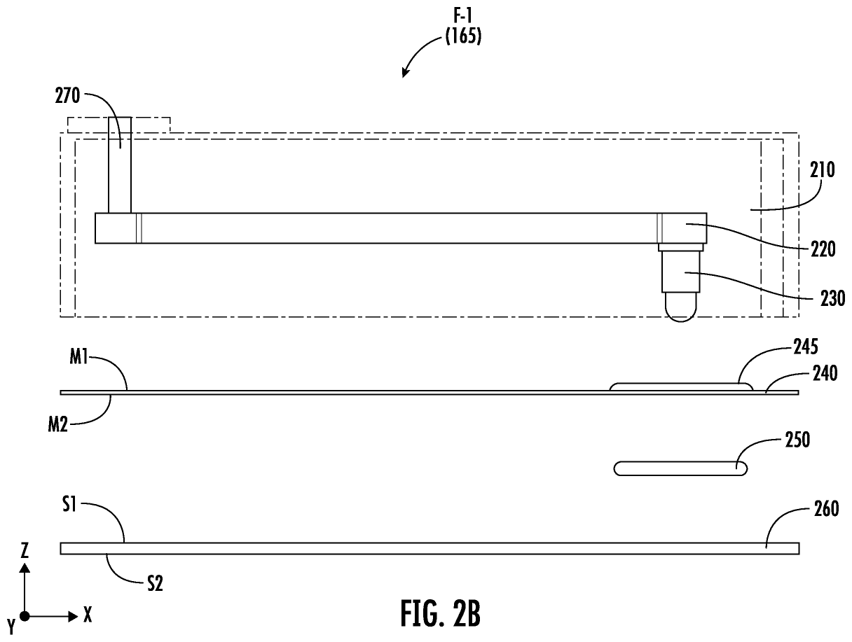

FIGS. 2A, 3A, 4A, 5A, and 6A are exploded side perspective views of different examples of an RF cavity filter F of the filter device 165 of FIG. 1C, according to embodiments of the present invention. FIGS. 2B, 3B, 4B, 5B, and 6B are exploded side views of the filters F of FIGS. 2A, 3A, 4A, 5A, and 6A, respectively.

As shown in FIG. 2A, a first RF cavity filter F-1 includes a conductive (e.g., metal) housing 210 and a plurality of resonators 222 that are surrounded by walls of the housing 210. The resonators 222 may all extend from an RF transmission line 221. In some embodiments, the transmission line 221 and the resonators 222 may each be part of a single (i.e., monolithic) flat metal piece 220. Moreover, each resonator 222 may, according to some embodiments, include resonator head and a resonator stalk that is between the resonator head and the transmission line 221.

For simplicity of illustration, three in-line resonators 222 that are physically connected to each other by the transmission line 221 are shown in FIG. 2A. In some embodiments, however, more or fewer resonators 222 may be inside the housing 210. For example, the walls of the housing 210 may surround four, five, or more resonators 222, or only one or two resonators 222.

One side (e.g., a front or rear) of the resonators 222 may be covered by a metal cover 240 that has an opening 240H therein. According to some embodiments, a protruding (e.g., raised by metal punching) annular portion 245 of the metal cover 240 may protrude from a first surface M1 (e.g., a flat primary surface) of the metal cover 240 toward the transmission line 221 and provide a perimeter around the opening 240H, as shown in FIGS. 2A and 2B.

A PCB 260 may cover the metal cover 240 (and the resonators 222 that are covered by the metal cover 240), and a conductive ring 250 may be between the metal cover 240 and the PCB 260. In some embodiments, a second surface M2 of the metal cover 240 that is opposite the first surface M1 may comprise a recessed portion that is configured to receive a portion (e.g., an upper half) of the conductive ring 250. The recessed portion may be formed by metal punching of the metal cover 240 that results in the protruding annular portion 245. Moreover, FIG. 2B illustrates that the protruding annular portion 245 protrudes in the direction Z away from the PCB 260.

The PCB 260 may be implemented as a feed board that couples the filter F-1 to a plurality of radiating elements RE (FIG. 9), or as an adaptor board that couples the filter F-1 to the radio 142 (FIG. 1B). Example adaptor boards are described in Italian Patent Application No. 102022000014683 to Wu et al., the disclosure of which is hereby incorporated herein by reference in its entirety. In other embodiments, the PCB 260 may be implemented as a calibration board. Example calibration circuits are discussed in U.S. Pat. No. 10,812,200 to Li et al., the entire content of which is incorporated herein by reference. Moreover, the PCB 260 may be implemented as either a single-layer PCB or a multi-layer PCB.

As shown in FIG. 2B, the PCB 260 may comprise a first surface S1 and a second surface S2 that is opposite the first surface S1. The first surface S1 may face the second surface M2 of the metal cover 240, and may be closer than the second surface S2 to the resonators 222. As the metal cover 240 is between the PCB 260 and the housing 210, the PCB 260 may not be soldered to the housing 210.

According to some embodiments, the PCB 260 may comprise a signal trace pad 261, an annular conductive region 263 that extends around the signal trace pad 261 and is coupled to electrical ground, and an annular insulation region 262 that is between the signal trace pad 261 and the annular conductive region 263. For example, the conductive ring 250 may be on (e.g., in contact with) the annular conductive region 263, and may thereby couple the metal cover 240 to electrical ground. The signal trace pad 261 may be implemented as an input/output node that couples the filter F-1 to the radio 142 or the radiating elements RE.

A pogo pin connector 230 that is coupled to the resonators 222 may extend in the direction Z through (i) the opening 240H and (ii) an opening in the conductive ring 250, and may be coupled to the PCB 260. For example, the pogo pin connector 230 may contact the signal trace pad 261 of the PCB 260. Moreover, the metal cover 240 may, in some embodiments, include the protruding annular portion 245, which may extend around (e.g., encircle a portion of) the pogo pin connector 230. The pogo pin connector 230 is an example of a pin-type RF connector, which may also be referred to herein as a “conductive pin.”

According to some embodiments, the pogo pin connector 230 may be a first RF connector that is on (e.g., in contact with) a first end of the transmission line 221. A second RF connector 270 may be on (e.g., in contact with) a second end of the transmission line 221 that is opposite the first end. The resonators 222 may thus each be coupled between the connectors 230, 270. The connectors 230, 270 may couple the resonators 222 to the radio 142 and the radiating elements RE, respectively, or vice versa.

In some embodiments, the conductive ring 250 comprises a silicone gasket that is embedded with metal particles. In other embodiments, a glue, adhesive, gasket, and/or foam that is conductive may be used in place of the conductive ring 250. A conductive material may thus be implemented in various forms around the opening 240H, such as in the recessed portion of the metal cover 240. Accordingly, the conductive material may extend around the pogo pin connector 230, and between the metal cover 240 and the PCB 260, and is not limited to being inside a circular silicone gasket. Moreover, the conductive material may be on (e.g., in contact with) the annular conductive region 263 of the PCB 260, and thus may be coupled to electrical ground via the annular conductive region 263.

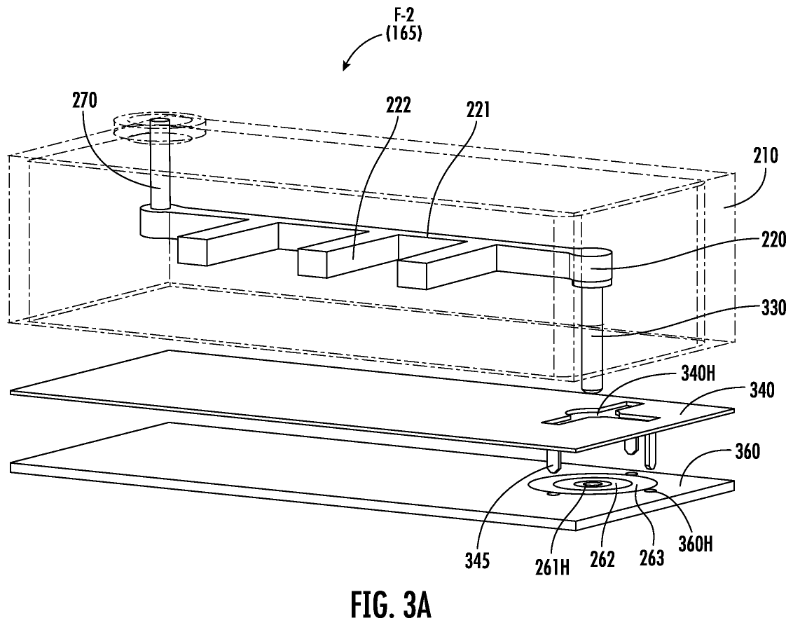

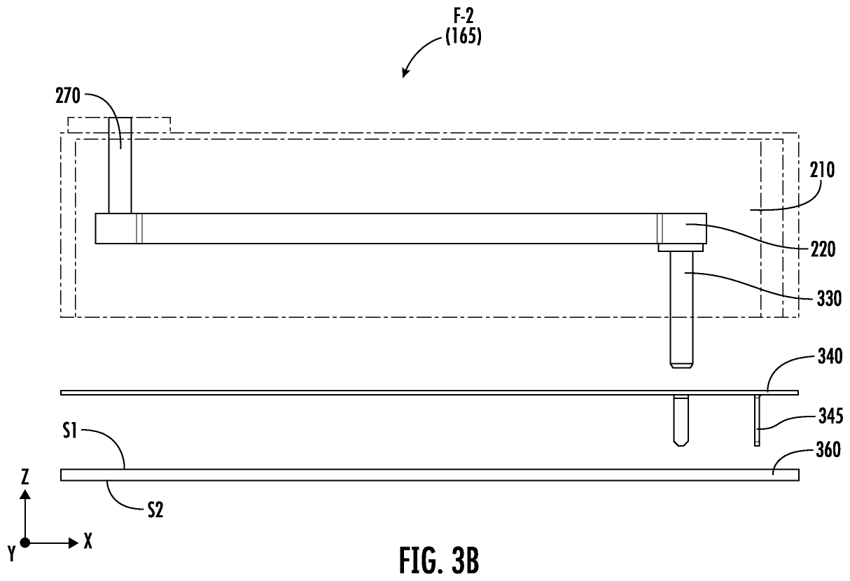

FIGS. 3A, 4A, 5A, and 6A (and FIGS. 3B, 4B, 5B, and 6B) show second, third, fourth, and fifth RF cavity filters F-2 through F-5, respectively, that each include the housing 210, the resonators 222, and the second RF connector 270. Differences between the second through fifth RF filters F-2 through F-5 and the first filter F-1 are described herein with respect to FIGS. 3A, 4A, 5A, and 6A (and/or FIGS. 3B, 4B, 5B, and 6B).

As shown in FIG. 3A, the second RF filter F-2 may include a metal cover 340 that has an opening 340H therein. The metal cover 340 may also have a plurality of built-in grounding pins 345 that are adjacent the opening 340H. For example, the grounding pins 345 may be bent/punched from a flat primary surface of the metal cover 340 to form the opening 340H. As shown in FIG. 3B, the grounding pins 345 may each extend in the direction Z from the flat primary surface of the metal cover 340 toward a PCB 360.

For example, FIG. 3A illustrates that the PCB 360 may include a plurality of PTHs 360H therein, and FIG. 3B illustrates that the PCB 360 has a first surface S1 and a second surface S2 that is opposite the first surface S1. The first surface S1 is closer than the second surface S2 to the flat primary surface of the metal cover 340. The grounding pins 345 may extend through respective ones of the PTHs 360H and may be soldered to the second surface S2. The grounding pins 345 may thus each extend into (e.g., through) the PCB 360.

The PCB 360 may also have a PTH 261H therein that is between (e.g., centered between) the PTHs 360H. For example, the annular insulation region 262 and the annular conductive region 263 may each extend around the PTH 261H, and the PTHs 360H may be along a perimeter of the annular conductive region 263. A conductive pin 330 that is coupled to the RF transmission line 221 can extend through the opening 340H and into (e.g., through) the PTH 261H. In some embodiments, the conductive pin 330 may be soldered to the second surface S2 of the PCB 360. The conductive pin 330 is an example of a pin-type RF connector that is not a pogo pin connector. Moreover, the PCB 360, like the PCB 260 (FIG. 2A) may be implemented as either a multi-layer PCB or a single-layer PCB, and/or may be implemented as a feed board, an adaptor board, or a calibration board.

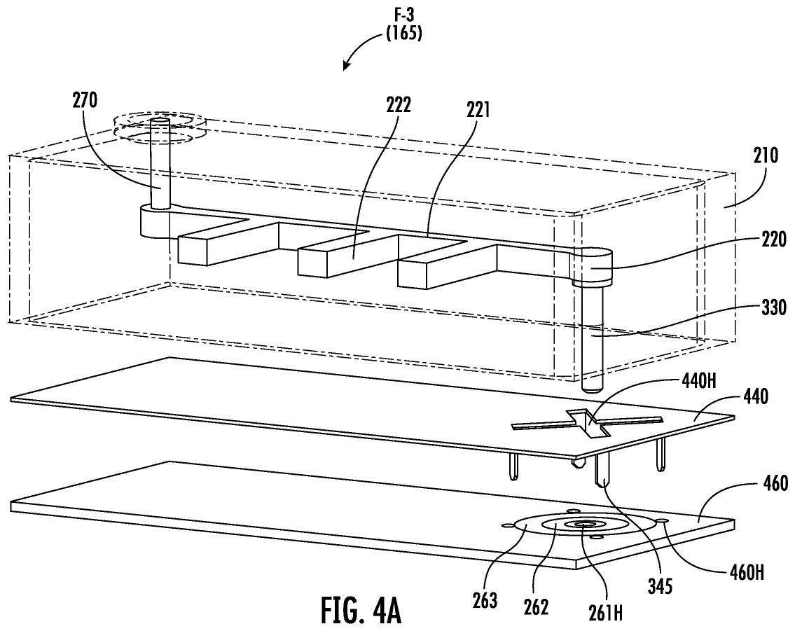

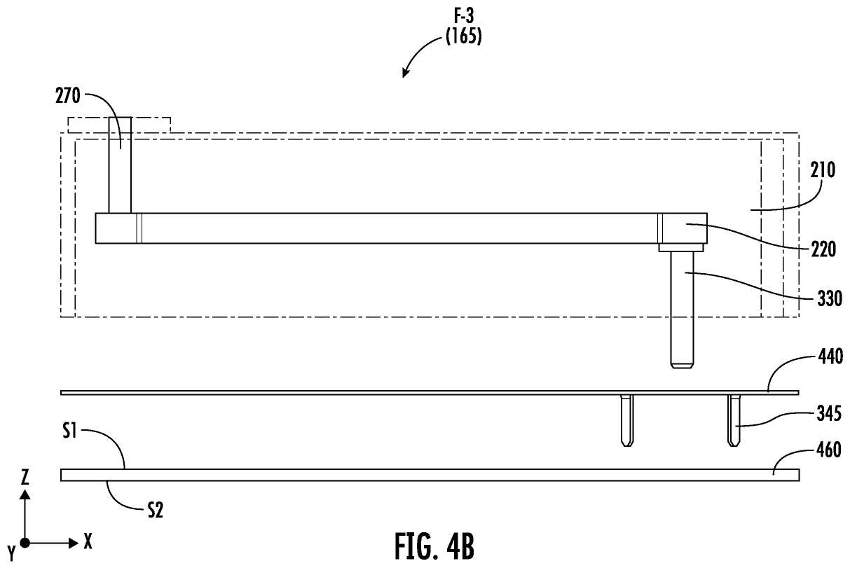

As shown in FIG. 4A, the third RF filter F-3 may include a metal cover 440 that has an opening 440H therein. The metal cover 440 may also have a plurality of built-in grounding pins 345 that are adjacent the opening 440H. For example, the grounding pins 345 may be bent/punched from a flat primary surface of the metal cover 440 to form the opening 440H. As shown in FIG. 4B, the grounding pins 345 may each extend in the direction Z from the flat primary surface of the metal cover 440 toward a PCB 460.

The metal cover 440 differs from the metal cover 340 (FIG. 3A), in that the metal cover 440 has four grounding pins 345, whereas the metal cover 340 has three grounding pins 345. Also, the PCB 460 differs from the PCB 360 (FIG. 3A), in that the PCB 460 has four PTHs 460H, whereas the PCB 360 has three PTHs 360H. The four PTHs 460H receive the four grounding pins 345, respectively. In some embodiments, the four grounding pins 345 may be soldered to a second surface S2 of the PCB 460 that is opposite a first surface S1 thereof that is closer than the second surface S2 to a flat primary surface of the metal cover 440. Moreover, the conductive pin 330 may be between the four grounding pins 345 and may extend into the PTH 261H in the PCB 460.

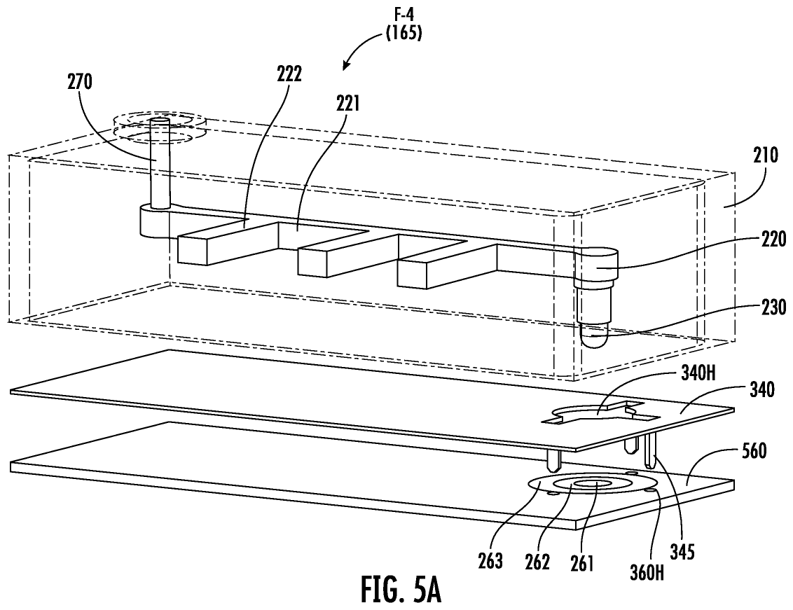

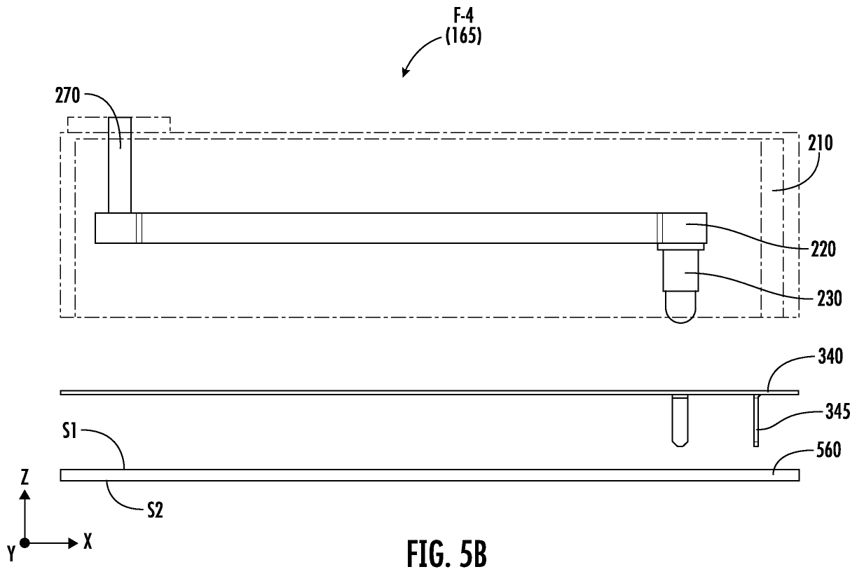

As shown in FIG. 5A, the fourth filter F-4 may include a pogo pin connector 230 that extends through the opening 340H of the metal cover 340 and is coupled to (e.g., in contact with) a signal trace pad 261 of a PCB 560. The PCB 560 differs from the PCB 360 of FIG. 3A, in that the PCB 560 has the signal trace pad 261 instead of a PTH 261H (FIG. 3A). Accordingly, the pogo pin connector 230 does not extend into or through the PCB 560. Referring to FIG. 5B, the pogo pin connector 230 thus is not soldered to a second surface S2 of the PCB 560 that is farther than a first surface S1 thereof from a flat primary surface of the metal cover 340.

Accordingly, FIGS. 3A, 3B, 4A, 4B, 5A, and 5B illustrate that a metal cover may have at least three grounding pins 345. Each grounding pin 345 may be coupled to electrical ground by the PCB 360, the PCB 460, or the PCB 560, such as via an annular conductive region 263 thereof. According to some embodiments, the annular conductive region 263 can be omitted from the filters F-2 through F-5 that are shown in FIGS. 3A, 4A, 5A, and 6A. Moreover, in some embodiments, electrical ground may be provided by a ground plane, such as a copper layer, that is on the second surface S2 of the PCB.

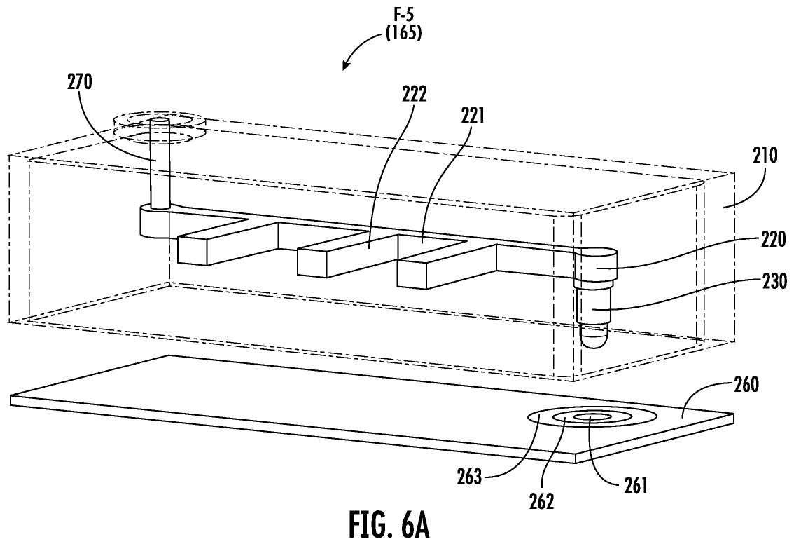

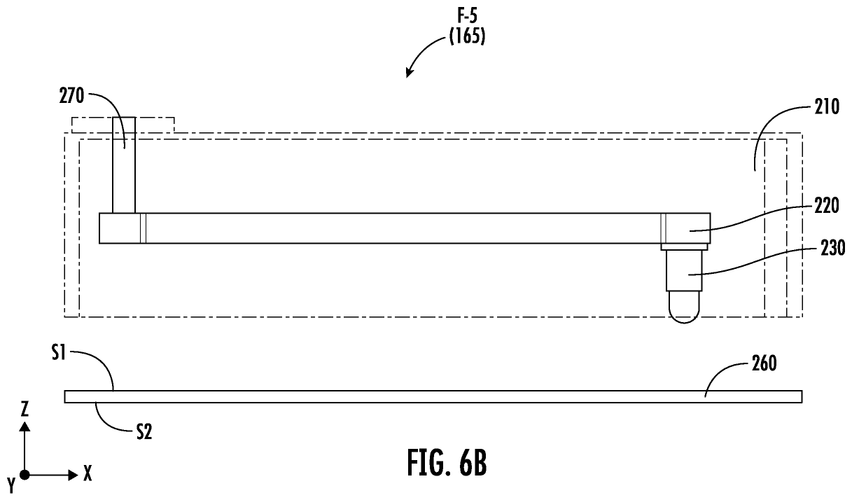

As shown in FIGS. 6A and 6B, the fifth filter F-5 may omit the metal cover 240 and the conductive ring 250 that are shown in FIGS. 2A and 2B. Accordingly, the PCB 260 may be soldered to the conductive housing 210 of the fifth filter F-5, as no metal cover is therebetween. For example, a perimeter portion of a first surface S1 of the PCB 260 may be soldered to a perimeter portion of the housing 210. The first surface S1 may be opposite a second surface S2 of the PCB 260 that is farther than the first surface S1 from the housing 210.

For simplicity of illustration, only one opening of the housing 210 in FIGS. 2A, 2B, 3A, 3B, 4A, 4B, 5A, 5B, 6A, and 6B is shown as being covered with a PCB. In some embodiments, however, opposite openings of the housing 210 may be covered with respective PCBs. Accordingly, first and second RF connectors 230 (or 330), 270 that are at least partially inside the housing 210 may couple the resonators 222 to first and second PCBs, respectively. For example, the first and second PCBs may be implemented as different ones of the PCBs 260, 360, 460, 560 that are shown in FIGS. 2A, 2B, 3A, 3B, 4A, 4B, 5A, 5B, 6A, and 6B. Moreover, the first and second PCBs may be implemented as a feed board and an adaptor board, respectively, or vice versa. In other embodiments, any of the PCBs 260, 360, 460, 560 may be implemented as a calibration board.

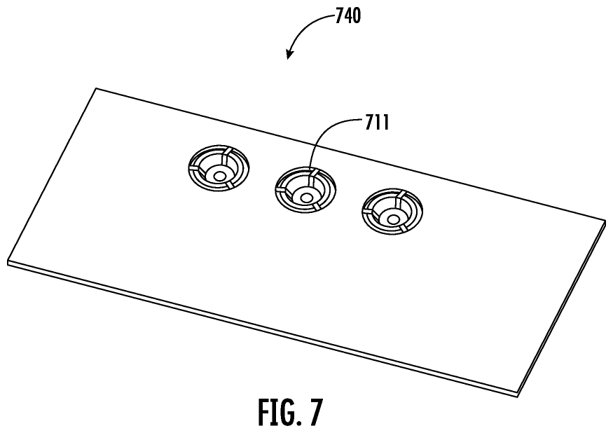

FIG. 7 is a front perspective view of a metal cover 740 that includes a plurality of adjustable tuning elements 711 therein, according to embodiments of the present invention. For example, the tuning elements 711 may comprise respective twistable tuning elements with circular/loop regions (e.g., of cap/basket shapes). In some embodiments, the tuning elements 711 may be implemented in the metal covers 240 (FIG. 2A), 340 (FIG. 3A), and/or 440 (FIG. 4A). The metal covers 240, 340, and/or 440 may thus be tuning covers that are configured to tune resonance frequencies and couplings between resonators 222. Example tuning elements and methods of tuning are discussed in U.S. Pat. No. 10,050,323 to Tkadlec et al., the entire content of which is incorporated herein by reference.

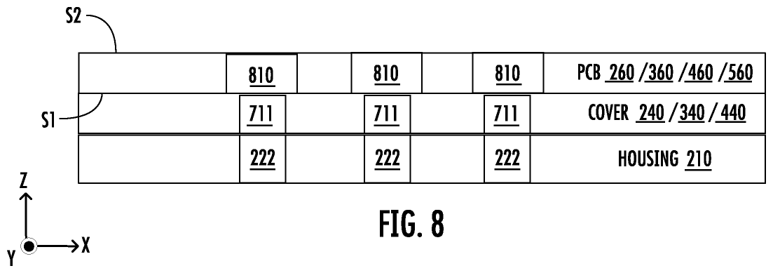

FIG. 8 is a schematic cross-sectional view of a PCB with openings 810 therein that correspond to the tuning elements 711, respectively, of FIG. 7. For example, the openings 810 may be implemented in the PCBs 260 (FIG. 2A), 360 (FIG. 3A), 460 (FIG. 4A), and/or 560 (FIG. 5A). The openings 810 may provide access for a person to adjust the tuning elements 711. For example, FIG. 8 shows that the openings 810 may overlap the tuning elements 711, respectively, in the direction Z.

In some embodiments, the tuning elements 711 may overlap, in the direction Z, the resonators 222, respectively. In other embodiments, one or more of the tuning elements 711 may be between, in the direction X, pairs of the resonators 222.

FIG. 9 is a schematic side view of a feed board 960 that covers resonators 222 of FIG. 6A. As shown in FIG. 9, the feed board 960 feeds a plurality of radiating elements RE that project in the direction Z from the feed board 960. For simplicity of illustration, three radiating elements RE are shown on the feed board 960. In some embodiments, however, the feed board 960 may feed more (e.g., four, five, or more) or fewer (e.g., one or two) radiating elements RE. Moreover, though the feed board 960 is illustrated as covering resonators 222 of FIG. 6A, any of the PCBs 260 (FIG. 2A), 360 (FIG. 3A), 460 (FIG. 4A), and/or 560 (FIG. 5A) may be implemented as the feed board 960, and thus may be coupled between resonators 222 and radiating elements RE.

The radiating elements RE may have various shapes and/or structures, and thus are not limited to the example shapes/structures shown in FIG. 9. For example, the radiating elements RE may be sheet-metal radiating elements that may be implemented with various shapes and/or feeding techniques. In some embodiments, the radiating elements RE may be patch radiating elements or crossed-dipole radiating elements.

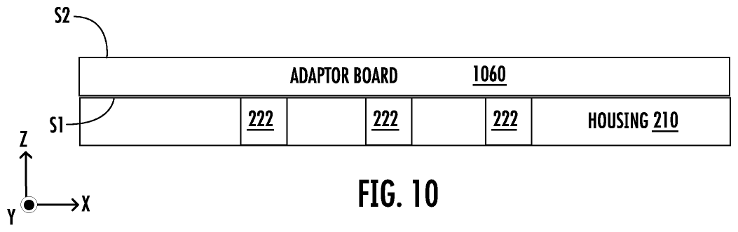

FIG. 10 is a schematic side view of an adaptor board 1060 that covers resonators 222 of FIG. 2A. The adaptor board 1060 may couple the resonators 222 to the radio 142 (FIG. 1B). In some embodiments, any of the PCBs 260 (FIG. 2A), 360 (FIG. 3A), 460 (FIG. 4A), and/or 560 (FIG. 5A) may be implemented as the adaptor board 1060, and thus may be coupled between resonators 222 and the radio 142.

For simplicity of illustration, the metal cover 240 of FIG. 2A is omitted from view in FIG. 10. Moreover, RF connectors 230 (or 330), 270 are omitted from view in FIGS. 8-10. It will be understood, however, that the housing 210 may comprise two RF connectors 230 (or 330), 270 therein that are coupled to the resonators 222.

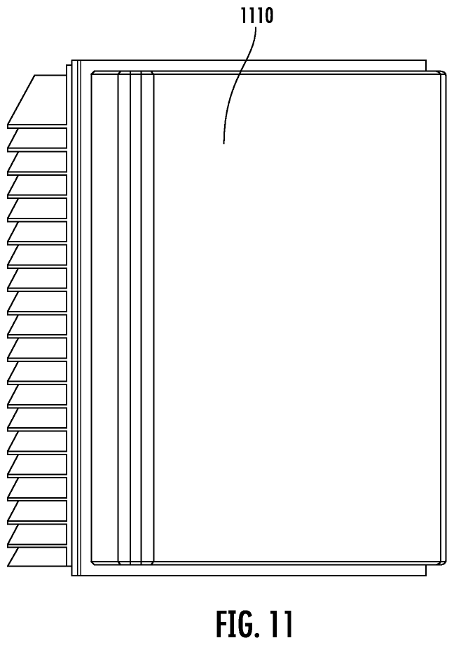

FIG. 11 is a front perspective view of a base station antenna radome 1110, according to other embodiments of the present invention. The antenna 100 is thus not limited to the radome 110 that is shown in FIG. 1A. Nor is the antenna 100 limited to a particular generation of cellular communications technology. Rather, the antenna 100 may be implemented with various types of radomes and/or various generations of cellular communications technology. In some embodiments, the antenna 100 may be implemented with the radome 1110, which may be, for example, a fifth generation (“5G”) massive MIMO radome. The antenna 100 is not limited, however, to being either a fourth generation (“4G”) base station antenna or a 5G (e.g., 5G massive MIMO) base station antenna.

RF devices according to embodiments of the present invention may provide a number of advantages. These advantages include decreasing the cost and/or size of an RF cavity filter by using a PCB that covers a conductive housing of the filter and an RF connector that is at least partially inside the conductive housing and coupled to the PCB. In contrast, a conventional cellular base station may include additional RF connectors between a filter and a PCB, which can increase the cost and/or size of the cellular base station.

A further advantage includes electromagnetic shielding that can be provided by the conductive ring 250 for the pogo pin connector 230 that extends through the conductive ring 250 in the first filter F-1, as shown in FIG. 2A. The first filter F-1 may also have a solderless transition between the PCB 260 (FIG. 2A) and the conductive housing 210 (FIG. 2A), as the metal cover 240 (FIG. 2A) is between the PCB 260 and the housing 210.

According to some embodiments, the second filter F-2 may have built-in grounding pins 345 (FIG. 3A) that can be used to couple the metal cover 340 (FIG. 3A) to electrical ground. For example, the grounding pins 345 can be used instead of an extra component (e.g., the conductive ring 250) that is separate from the metal cover 340 to provide electrical grounding. Moreover, the grounding pins 345 can provide electromagnetic shielding for the conductive pin 330 (FIG. 3A) that extends between the grounding pins 345.

In some embodiments, four or more built-in grounding pins 345 can be used, as shown in the third filter F-3 of FIG. 4A. This can increase electromagnetic shielding for the conductive pin 330 relative to embodiments in which three or fewer grounding pins 345 are used.

According to some embodiments, the pogo pin connector 230 may be used instead of the conductive pin 330. Because the pogo pin connector 230 does not extend through the PCB 560 (FIG. 5A) of the fourth filter F-4, and thus is not exposed on the second surface S2 (FIG. 5B) of the PCB 560, electromagnetic shielding for the pogo pin connector 230 may increase relative to that for the conductive pin 330. Moreover, the pogo pin connector 230 has a solderless connection to the PCB 560.

In some embodiments, the pogo pin connector 230 of the fifth filter F-5 (FIG. 6A) may be coupled to (e.g., in contact with) the PCB 260 without passing through any metal cover. The fifth filter F-5 may thus be free of any tuning elements 711 (FIG. 7) or grounding pins 345. Electromagnetic shielding for the pogo pin 230 may increase because no grounding pin 345 (and no conductive pin 330) extends to the second surface S2 (FIG. 6B) of the PCB 260. Moreover, electrical grounding may be provided by soldering the PCB 260 to the conductive housing 210. Accordingly, no additional electrical grounding may be needed.

According to some embodiments, any metal cover herein may comprise tuning elements 711 therein. This tuning capability may allow the filters F to be integrated with various types of PCBs, such as various types of adaptor boards. Moreover, a PCB that covers the metal cover may include cutouts/openings 810 (FIG. 8) therein that provide user access to the tuning elements 711.

The present invention has been described above with reference to the accompanying drawings. The present invention is not limited to the illustrated embodiments. Rather, these embodiments are intended to fully and completely disclose the present invention to those skilled in this art. In the drawings, like numbers refer to like elements throughout. Thicknesses and dimensions of some components may be exaggerated for clarity.

Spatially relative terms, such as “under,” “below,” “lower,” “over,” “upper,” “top,” “bottom,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the example term “under” can encompass both an orientation of over and under. The device may be otherwise oriented (rotated 90 degrees or at other orientations) and the spatially relative descriptors used herein interpreted accordingly.

Herein, the terms “attached,” “connected,” “interconnected,” “contacting,” “mounted,” “coupled,” and the like can mean either direct or indirect attachment or coupling between elements, unless stated otherwise.

Well-known functions or constructions may not be described in detail for brevity and/or clarity. As used herein the expression “and/or” includes any and all combinations of one or more of the associated listed items.

The terminology used herein is for the purpose of describing particular embodiments only and is not intended to be limiting of the present invention. As used herein, the singular forms “a,” “an,” and “the” are intended to include the plural forms as well, unless the context clearly indicates otherwise. It will be further understood that the terms “comprises,” “comprising,” “includes,” and/or “including” when used in this specification, specify the presence of stated features, operations, elements, and/or components, but do not preclude the presence or addition of one or more other features, operations, elements, components, and/or groups thereof.

1. A radio frequency (RF) device comprising:
an RF filter comprising a resonator;
an RF connector that is coupled to the resonator; and
a printed circuit board (PCB) that covers the resonator and is coupled to the resonator via the RF connector.

2. The RF device of claim 1, wherein the RF connector comprises a pogo pin connector.

3. The RF device of claim 1,
wherein the PCB comprises a plated through hole (PTH), and
wherein the RF connector comprises a conductive pin that is coupled to the PTH.

4. The RF device of claim 3,
wherein a first surface of the PCB is opposite a second surface of the PCB and is closer than the second surface to the resonator, and
wherein the conductive pin extends into the PTH and is soldered to the second surface.

5. The RF device of claim 1, further comprising a metal cover that is between the PCB and the resonator,
wherein the RF connector extends through an opening in the metal cover.

6. The RF device of claim 5, further comprising a conductive ring that is between the metal cover and the PCB,
wherein the RF connector extends through the conductive ring.

7. The RF device of claim 5,
wherein the RF filter further comprises a conductive housing having walls that extend around the resonator, and
wherein the PCB is not soldered to the conductive housing.

8. The RF device of claim 5, wherein the metal cover comprises a grounding pin that is adjacent the opening and extends into the PCB.

9. The RF device of claim 8, wherein the grounding pin comprises a first of at least three grounding pins of the metal cover that are adjacent the opening and extend into the PCB.

10. The RF device of claim 9, wherein the at least three grounding pins comprise respective punched portions of the metal cover.

11. The RF device of claim 9,
wherein the PCB comprises a plurality of plated through holes (PTHs),
wherein a first surface of the PCB is opposite a second surface of the PCB and is closer than the second surface to a flat primary surface of the metal cover, and
wherein the at least three grounding pins extend through respective ones of the PTHs and are soldered to the second surface.

12. The RF device of claim 9, wherein the at least three grounding pins comprise four grounding pins.

13. The RF device of claim 1,
wherein the RF filter further comprises a conductive housing having walls that extend around the resonator,
wherein the RF connector is a first RF connector that is at least partially inside the conductive housing,
wherein the RF device further comprises a second RF connector that is at least partially inside the conductive housing, and
wherein the resonator is coupled between the first and second RF connectors.

14. The RF device of claim 13,
wherein the resonator is a first of a plurality of resonators that are coupled between the first and second RF connectors,
wherein the PCB comprises a feed board that is configured to feed a plurality of radiating elements,
wherein the first RF connector is coupled between the resonators and the feed board, and
wherein the second RF connector is coupled between the resonators and a radio that is coupled to the radiating elements via the RF device.

15. The RF device of claim 13,
wherein the resonator is a first of a plurality of resonators that are coupled between the first and second RF connectors,
wherein the PCB is coupled between the first RF connector and a radio, and
wherein the second RF connector is coupled between the resonators and a plurality of radiating elements that are coupled to the radio via the RF device.

16. A radio frequency (RF) device comprising:
an RF filter comprising a plurality of resonators;
a metal cover that covers the resonators;
a printed circuit board (PCB) that covers the metal cover;
a conductive material that is between the metal cover and the PCB; and
a conductive pin that extends through the metal cover and the conductive material and couples the resonators and the PCB to each other.

17. The RF device of claim 16,
wherein the conductive pin comprises a pogo pin connector,
wherein the conductive material comprises metal that is inside a ring that extends around the pogo pin connector, and
wherein the metal cover comprises a flat primary surface and an annular portion that protrudes from the flat primary surface away from the PCB and extends around the pogo pin connector.

18. The RF device of claim 16,
wherein the RF filter further comprises a conductive housing having walls that extend around the resonators, and
wherein the PCB is not soldered to the conductive housing.

19. The RF device of claim 16,
wherein the metal cover comprises an adjustable tuning element therein, and
wherein the PCB comprises an opening that corresponds to the adjustable tuning element.

20. A radio frequency (RF) device comprising:
an RF filter comprising a plurality of resonators;
a printed circuit board (PCB) feed board that covers the resonators; and
a pogo pin connector that couples the resonators and the PCB feed board to each other.

21.-26. (canceled)
